(19) United States
(12) Patent Application Publication
(10) Pub. No.: US 2022/0157700 A1
(43) Pub. Date: May 19, 2022

(54) TWO SIDED BONDABLE LEAD FRAME

(71) Applicant: Texas Instruments Incorporated, Dallas, TX (US)

(72) Inventors: Dolores Babaran Milo, Baguio City (PH); Ernesto Pentecostes Rafael, Nueva Ecija (PH)

(21) Appl. No.: 17/590,663

(22) Filed: Feb. 1, 2022

Related U.S. Application Data
(63) Continuation of application No. 15/985,380, filed on May 21, 2018, now abandoned.

(51) Int. Cl. H01L 23/495; H01L 23/00; H05K 1/18

(52) U.S. Cl. CPC H01L 23/49568; H01L 23/49548; H01L 2924/1816; H05K 1/181; H01L 23/49513; H01L 24/48

(57) ABSTRACT

A lead frame includes a first side having a first die attach pad that is bondable to a die, and a second side that has a second die attach pad that is bondable to another die. The lead frame includes multiple leads on the edges of the lead frame to connect the die. As part of a no-leads device, such as a quad flat no leads (QFN) or dual flat no-leads (DFN), one of the die attach pads is used in binding to a die, and the other die attach pad is used for thermal dissipation and mounting to a structure such as printed circuit board (PCB).

This application is a continuation of U.S. application Ser. No. 15/985,380, filed May 21, 2018, the contents of which are herein incorporated by reference in its entirety.

### BACKGROUND

Lead frames are part of quad flat no-leads (QFN) and dual flat no-leads (DFN) packages or devices. No-leads packages or devices provide connections to surfaces of printed circuit boards (PCB) without through holes. The lead frames provide a specific surface for a die to be attached, where the die includes circuits and/or electrical connections. The lead frame further includes another specific surface for mounting to the PCB. This specific surface mounted to the PCB provides thermal dissipation, and particularly from the no-leads packages or devices. In designing and manufacturing lead frames, and the no-leads packages that the lead frames are part of, specific provisions are made for the surface used for die mounting and the surface used for PCB mounting and thermal dissipation.

### SUMMARY

The following presents a simplified summary in order to provide a basic understanding of one or more aspects of the invention. This summary is not an extensive overview of the invention, nor to delineate the scope thereof. Rather, the primary purpose of the summary is to present some concepts of the invention in a simplified form as a prelude to a more detailed description that is presented later.

Described herein is a lead frame that implements two pads used for connection to a structure, such as a printed circuit board (PCB). The two pads are on either side of the lead frame, and are bondable to a die. Connections are provided from the die to specific leads on the lead frame. Molding encapsulates the lead frame, die and connections, forming a flat no-leads, such as a dual or quad, package or device. The molding exposes the pad that is not used for binding to the die.

### BRIEF DESCRIPTION OF THE DRAWINGS

The detailed description is described with reference to accompanying figures. In the figures, the left-most digit(s) of a reference number identifies the figure in which the reference number first appears. The same numbers are used throughout the drawings to reference like features and components.

FIG. 1 is an isometric view of a lead frame with bondable pads on both sides.

FIG. 2 is a cross sectional view of a lead frame with bondable pads on both sides.

FIG. 3 is a cross sectional view of a lead frame with a first side and second side and leads.

FIG. 4 is a view of a lead frame with a die bonded to one die attach pad on one side and a view of the lead frame with an exposed die attach pad on the other side.

FIG. 5 is a view of partial cross sectional view of a flat no-leads package having a lead frame with die attach pad for binding to a die and another die attach pad exposed by the package.

FIG. 6 is a view of the bottom of a quad flat no-leads package having a lead frame with two bondable die attach pads.

FIG. 7 is a process flow for manufacturing a lead frame with two bondable die attach pads.

FIG. 8 is a flow chart for manufacturing a flat no-leads package with two bondable die attach pads.

### DETAILED DESCRIPTION

Embodiments of the disclosure are described with reference to the attached figures. The figures are not drawn to scale and they are provided merely to illustrate the disclosure. Several aspects of the embodiments are described below with reference to example applications for illustration. It should be understood that numerous specific details, relationships, and methods are set forth to provide an understanding of the disclosure. One skilled in the relevant art, however, will readily recognize that the disclosure can be practiced without one or more of the specific details or with other methods. In other instances, well-known structures or operations are not shown in detail to avoid obscuring the disclosure. The embodiments are not limited by the illustrated ordering of acts or events, as some acts may occur in different orders and/or concurrently with other acts or events. Furthermore, not all illustrated acts or events are required to implement a methodology in accordance with the present disclosure.

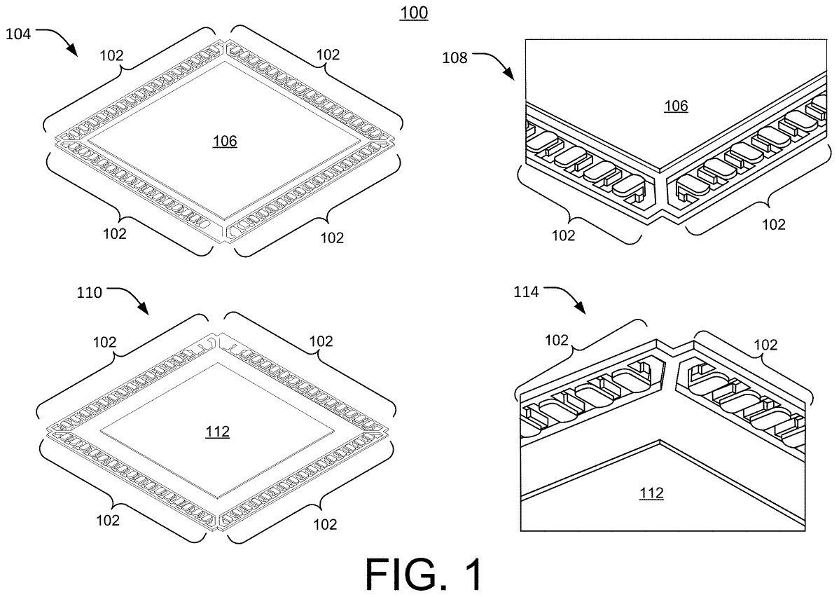

FIG. 1 shows isometric views of a lead frame 100. Lead frame 100 is part of a flat no-leads package or device. The no-leads package or device can be a quad flat no-leads (QFN) or a dual flat no-leads (DFN) package or device. The package or device is also considered as a semiconductor package or device. The no-leads package or device implements surface mount technology that allows connections of dies, to surfaces of printed circuit boards (PCB). In certain implementations the connections in the die are circuits.

The lead frame 100 includes multiple leads 102. In a complete DFN or QFN package or device, the leads 102 provide electrical connections to the PCB. The view 104 shows a first side, such as a top side of the lead frame 100 and the multiple leads 102, and a die attach pad 106. For certain implementations, die attach pad 106 is used as a surface to bind to a die. View 108 is an enlarged sectional view of the first side or top side of the lead frame 100.

View 110 shows a second side, such as a bottom side of lead frame 100. The second side or bottom side includes another die attach pad 112. Die attach pad 106 is used as a surface to bind to a die. Therefore, either die attach pad 106 or die attach pad 112 is used as surface to bind to a die. The die attach pad that is used to bind to the die is determined based on die size requirement. Therefore, die attach pad 106 is used for binding to a particular die, while die attach pad 112 is used for binding to another die.

In the package or device (e.g., semiconductor package), the die attach pad that is not used to bind to the die, is exposed. The exposed die attach pad, either die attach pad 106 or die attach pad 112 is used for connectivity to a structure, such as a PCB.

As shown in views 104 and 110, lead frame 100 is rectangle or square in shaped in area. Die attach pad 106 and die attach pad 112 are also shown as rectangle or square in area. It is to be understood that lead frame 100, die attach pad 106 and die attach pad 112 in other implementations have different area shapes. Because die attach pad 106 and die attach pad 112 are different in area size, die attach pad 106 and die attach pad 112 provide different thermal dissipation characteristics. In this example, die attach pad 106 is larger than die attach pad 112 and is able to dissipate more heat from the package or device.

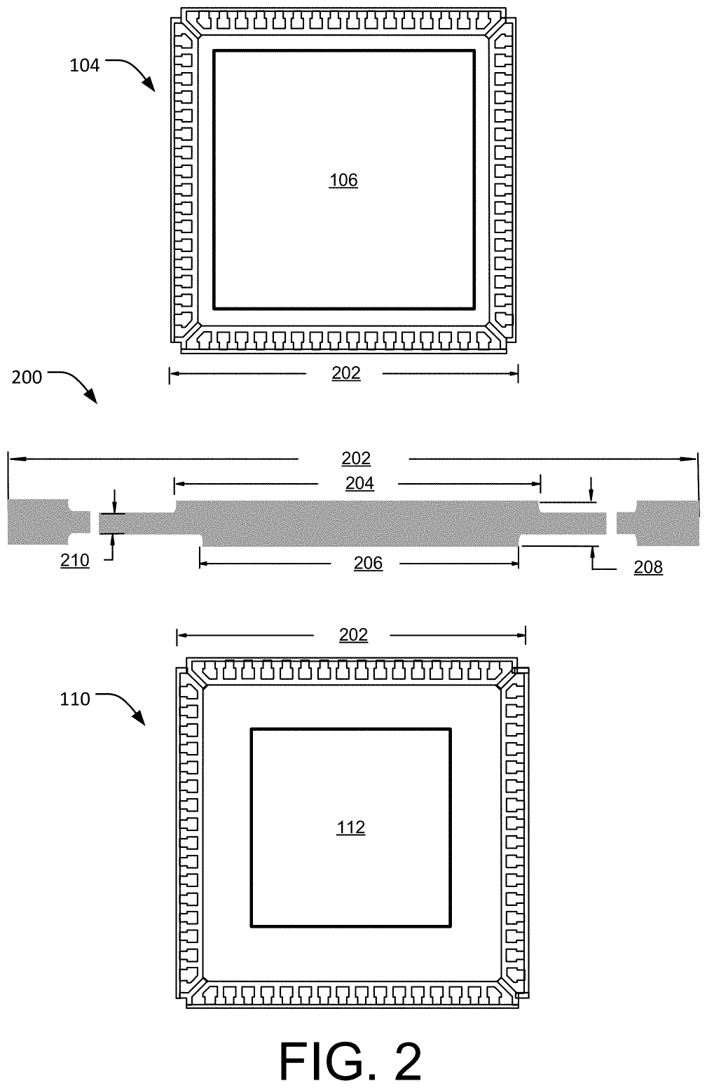

FIG. 2 shows a cross sectional view 200 of lead frame 100. The first or top view 104 is shown with die pad 106. The second or bottom view 110 is shown with die attach pad 112. In this example, the area of die attach pad 106 is larger in size than the area of die attach pad 112. As discussed above in this example, the areas of die attach pad 106 and die attach pad 112 are shown as rectangle or square in shape. In other implementations, it is to be understood that die attach pad 106 and die attach pad 112 are designed in configurations that are not rectangular or square in shape.

The cross sectional view 200 shows an edge dimension 202 of a single unit of a lead frame strip. An example value for lead edge dimension 202 is about 10.0 millimeters (mm). The cross sectional view 200 also shows a pad 106 edge dimension of 204. An example value for die attach pad 106 edge dimension of 204 is about 7.6 mm. Furthermore, cross sectional view 200 also shows a die attach pad 112 edge dimension of 206. An example value for edge dimension of 204 is about 6.2 mm. The overall thickness of lead frame 100 is represented by thickness 208. The middle thickness of lead frame 100 is represented by 210. Example values for thickness 208 is about 0.2 mm for the overall thickness of lead frame 100, and about 0.05 mm in thickness for both die attach pad 106 and die attach pad 112. In other words, the total thickness of lead frame 100 is about 0.2 mm, and the thicknesses for die attach pad 106 and die attach pad 112 are about 0.05 mm.

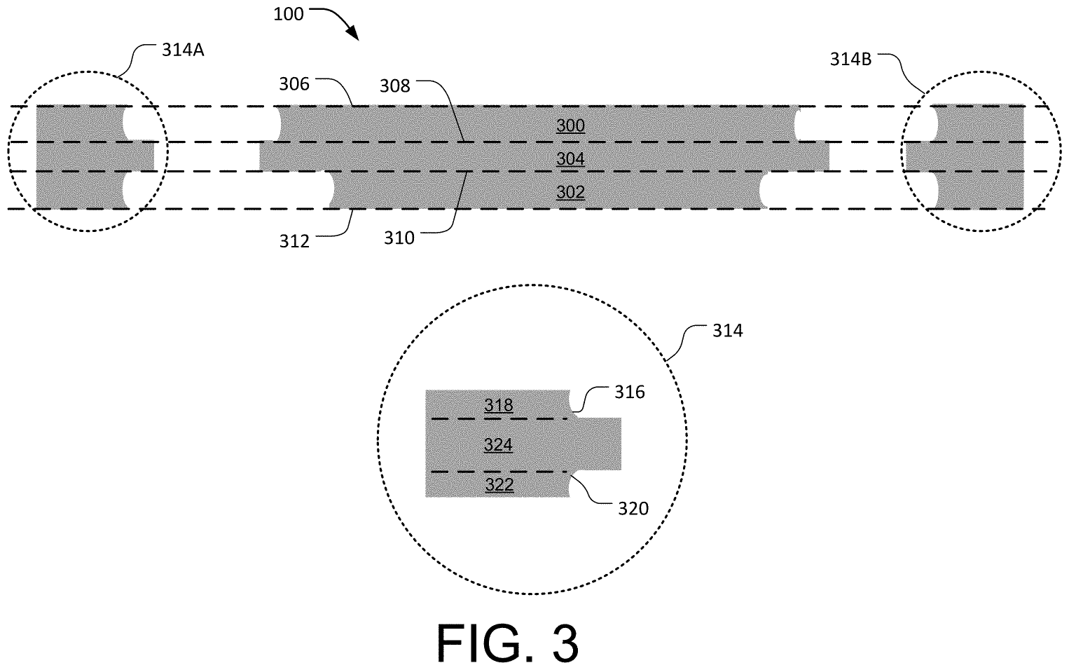

FIG. 3 shows a cross sectional view defining planes of lead frame 100. FIG. 3 further shows a cross sectional view of a lead, such as leads 102 described above. The lead frame has first or top side 300, a second or bottom side 302, and a middle section 304. The first or top side 300 is defined by plane 306 and plane 308. The middle section 304 is defined by plane 308 and plane 310. The second or bottom side is defined by plane 310 and plane 312.

The first or top side 300 and second or bottom side 302 provide for die attach pads (i.e., bonding pads). Such die attach pads having different size in area and provide different thermal dissipation characteristics. For example, the first or top side 300 provides for die attach pad 106, and the second or bottom side 302 provides for die attach pad 112. As shown in this example, first or top side 300 is offset from the middle section 304, having an indentation as to middle section 304. Likewise, second or bottom side 302 has an indentation, which is greater than the indentation of first or second side 300, from middle section 304.

As implemented in a device or package, such as a QFN or DFN, one of the sides 300 or 302 will be exposed. The non-exposed side will be used for bonding to a die. Such an implementation is different than an implementation where both sides are used for bonding to different dies as implemented in multi-chip/multi-die configurations.

The lead frame 100 includes leads 314A and 314B. Leads 314A and 314B are leads such as leads 102 described above. The leads 314A and 314B are formed after etching of first or top side 300 and second or bottom side 302. Etching is further described below. An expanded view of lead 314 is shown in FIG. 3. In this example, lead 314 has an indentation 316 on one side 318 or an indentation on a top plane of the lead frame, and another indentation 318 on another side 322 or an indentation of a bottom plane of the lead frame. A middle section 324 of lead 314 is also shown. The indentations are generally curved in shape. In certain implementations the indentations are right angled cut or right angle in shape.

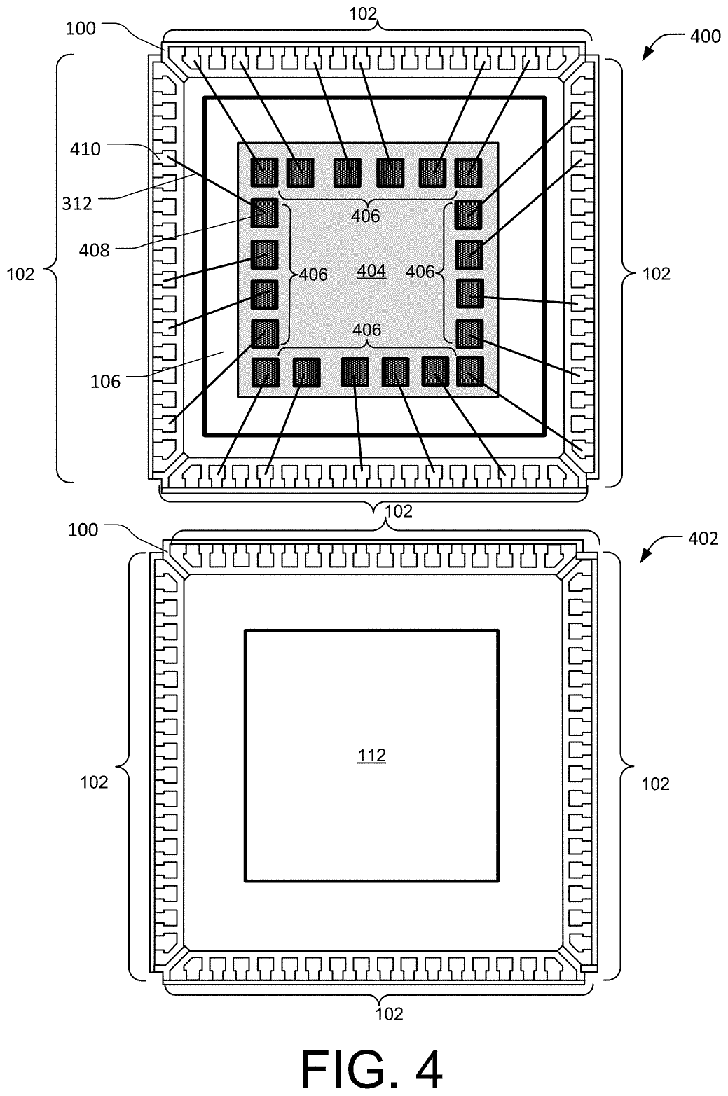

FIG. 4 shows lead frame 100 with a top view 400 and a bottom view 402. Die attach pad 106 is shown in top view 400 and die attach pad 112 is shown in bottom view 402. Lead frame 100 is processed such that either die attach pad 106 or die attach pad 112 is used for thermal dissipation and/or connectivity to a structure such as a PCB. As discussed above die attach pad 106 is different in area size than die attach pad 112. The die attach pad that is not used for thermal dissipation and/or connectivity to a structure is used for binding to a die.

In this example, die attach pad 106 is used to bind a die 404. Die 404 includes circuits and connections. Bond pads 406 connect the circuits and connections of die 404. As represented by bond pad 408, bond pads 406, are connected to particular leads of the multiple leads 102. In this example, bond pad 408 is connected to lead 410 by wire 412. Therefore, die 404 is electrically connected to at least one of the multiple leads 102. As shown in FIG. 4, other bond pads of bond pads 406 are connected to particular leads of the multiple leads, by particular wires or electrically connected. The connections are predetermined by design requirements as to connectivity of die 404.

The bottom view 402 shows die attach pad 112. In this example, die attach pad 112 is used as for thermal dissipation and connectivity to a structure such as a PCB, for a QFN or DFN package or device that incorporates the lead frame 100. Die attach pad 112 is exposed as part of the package or device.

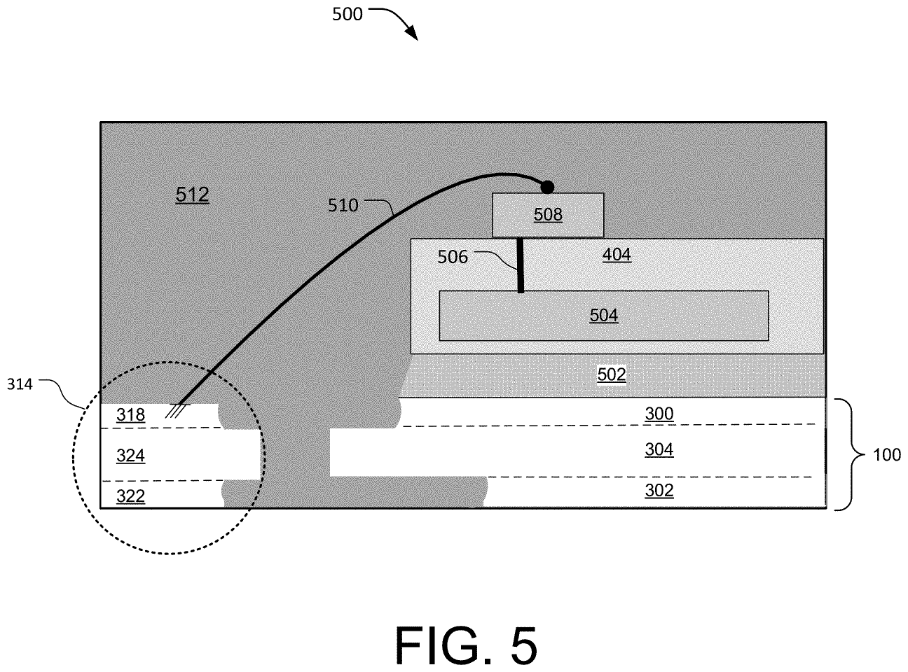

FIG. 5 shows a partial cross sectional view of a QFN or DFN package or device 500. Device 500 is also considered as a semiconductor package. Lead frame 100 is bound to die 404 by binding layer 502. Binding layer 502 is considered as die attach material. Examples of die attach material include an epoxy, laminate film, or other adhesion material. In particular, top side 300 which includes a pad, is bond to die 404 by binding layer 502. Bottom side 302 provides a pad for thermal dissipation and connection to a structure such as a PCB of the package or device 500. Bottom side 302 is exposed in the package or device 500.

Die 404 includes a circuit and internal connections 504. Circuit and internal connections 504 has a connection 506 to a bond pad 508. Bond pad 508 is one of the bond pads 406 of the die 404 as shown in FIG. 4.

Continuing to reference FIG. 4, an electrically connection or wire connection 510 connects bond pad 508 to lead 314. Wire connection 510 includes wire 412 as shown in FIG. 4. FIG. 5 further shows a molding 512 that encapsulates the lead frame 100, the binding layer 502, the die 404, bond pad 508, wire 510, and the lead 314. In certain embodiments, the molding 414 is plastic.

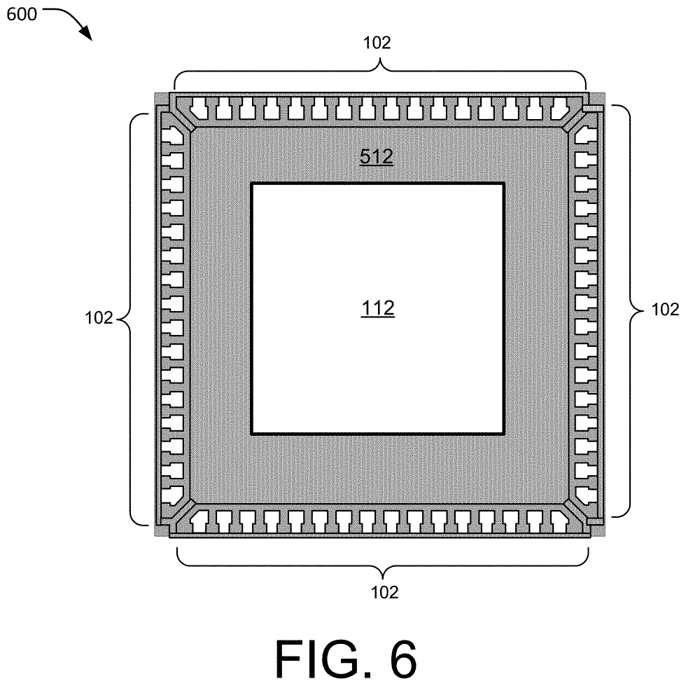

FIG. 6 shows a bottom view 600 of a QFN or DFN package or device. The QFN or DFN package or device is encapsulated with an encapsulation or molding 512. The molding 512 exposes the multiple leads 102 for connection to a structure such as a PCB. The encapsulation or molding 512 also exposes the die attach pad 112 for thermal dissipation and connectivity to a structure such as a PCB.

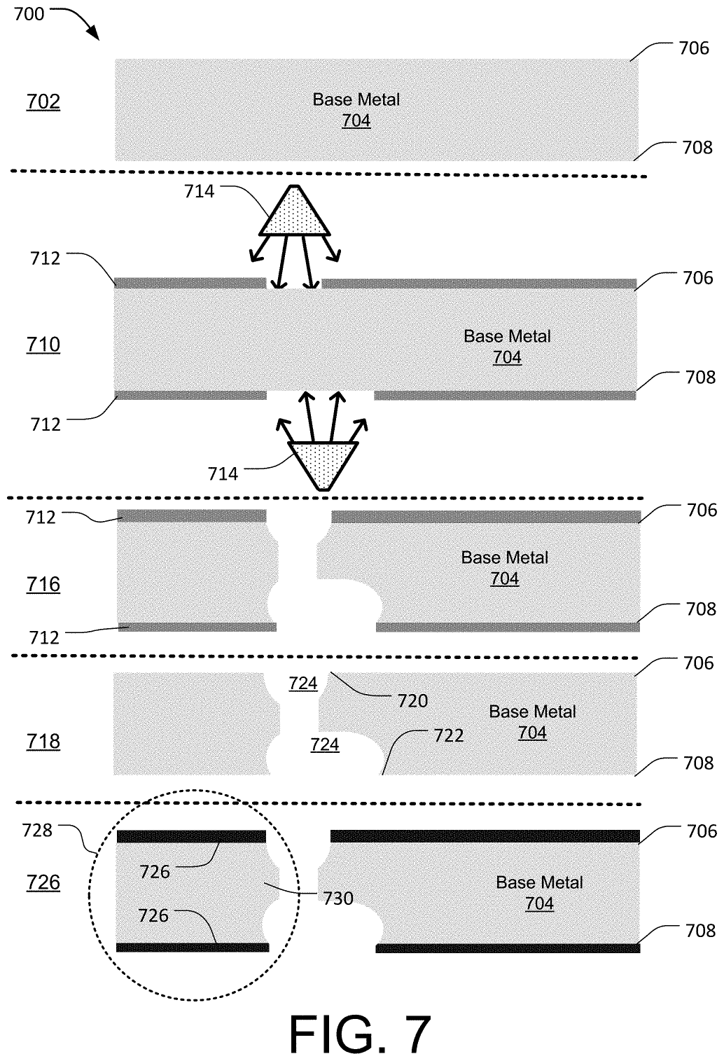

FIG. 7 shows process 700 for manufacturing a lead frame with two bondable pads.

At step 702, the lead frame starts with a base metal 704. In certain embodiments, the lead frame 704 is copper or copper alloy. The base metal 704 includes a top 706 and bottom 708.

At step 710, a photo resist or artwork etching mask 712 is applied to the top 706 and the bottom 708, and a chemical etching 714 is performed.

At step 716, the photo resist or artwork etching mask 712 is removed.

At step 718, after the photo resist or artwork etching mask 712 is removed, a half edge 720 that defines a die attach pad of top 706 is provided. Likewise, a half edge 722 of a die attach pad of bottom side 708 is provided. In addition, through holes 724 are generated during etching. The through holes 724 prevent shorting of the base metal 704. The through holes provide for connection from bond pads of a die and from bond pads of another die.

At step 726, plating 728 and polishing is performed on the metal 704. A lead 728 is provided. Lead 728 has the shape described above in reference to lead 314, where lead 728 has an indentation on top 706, and another indentation on bottom 708. The indentations are generally curved in shape. In certain implementations the indentations are right angled cut or right angle in shape. A middle section 730 of lead 728 is shown.

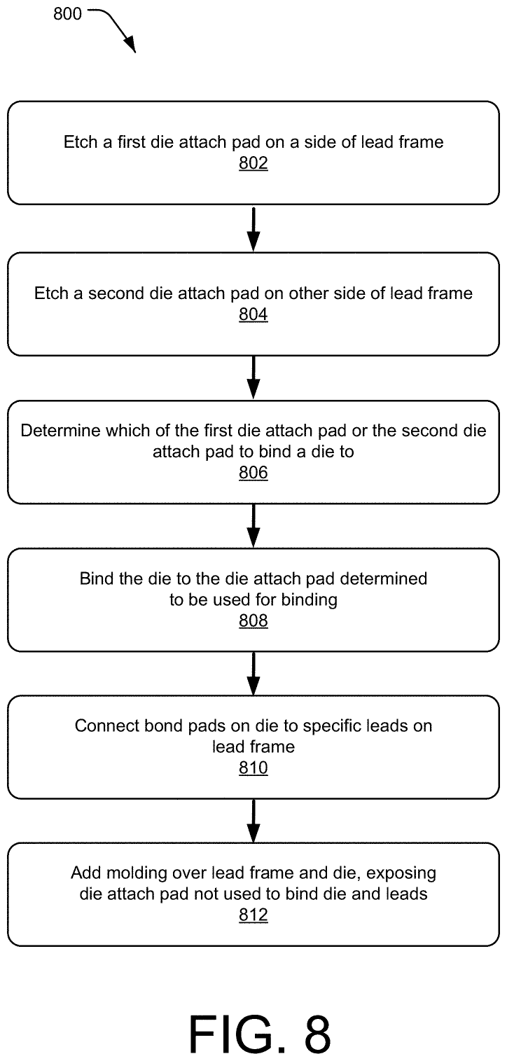

FIG. 8 shows an example flow chart 800 for a method of fabricating a no-leads device die attach pads.

At block 802, etching a first die attach pad on a first side of a lead frame is performed.

At block 804, etching a second die attach pad on a second side of the lead frame performed. In certain embodiments, blocks 802 and 804 are performed simultaneously. In certain embodiments, a chemical etching is performed. In certain embodiments, etching the first thermal pad defines edges of the first the die attach pad and the etching of the second die attach pad defines edges of the second die attach pad of another die bound to the second die attach pad. The etching also defines through holes as described above. In certain embodiments, plating and polishing of the lead frame are also performed.

At block 806, determining which of the first die attach pad or the second die attach pad to bind a die to is performed.

At block 808, binding the die to the die attach pad that is determined to bind the die to is performed.

At block 810, connecting bond pads on the die to specific leads of a set of leads that are part of the lead frame is performed.

At block 812, adding a molding over the lead frame and the die, wherein the specific leads and the die attach pad that is not used to bind the die are exposed is performed.

What is claimed is:

1. A semiconductor package comprising:
a portion of a lead frame comprising:
a first side that includes a first die attach pad bondable to a die;
a second side that includes a second die attach pad bondable to another die;
a middle section between the first side and the second side, wherein the first die attach pad and the second die attach pad projects from the middle section at a first height and a second height respectively;
multiple leads on the edges of the lead frame used for die connection; and
encapsulation that covers the lead frame and exposes at least one of the first die attach pad or the second die attach pad and the multiple leads.

2. The semiconductor package of claim 1, wherein the first die attach pad and second die attach pad are different in size by area and provide different thermal dissipation characteristics.

3. The semiconductor package of claim 1, wherein as viewed from a cross section of the lead frame, a middle section of the lead frame, the first side, and second side are on different planes.

4. The semiconductor package of claim 1, wherein binding of either the first die attach pad to the die or the second die attach to the another die, uses one of an epoxy, laminate film, or adhesion material.

5. The semiconductor package of claim 1, wherein as viewed from a cross section of the lead frame, the lead frame has a total thickness of about 0.2 millimeters and the first die attach pad and second die attach pad are each about 0.05 millimeters in thickness.

6. The semiconductor package of claim 1, wherein as viewed from a top or bottom view the first die attach pad, the second die attach pad, and the middle section are rectangular in area.

7. The semiconductor package of claim 1, wherein the multiple leads are shaped with an indentation on a top plane of the lead frame and an indentation on a bottom plane of the lead frame, wherein the indentations are curved or have a right angled cut.

8. The semiconductor package of claim 1, wherein the first die attach pad and second die attach pad are about square in area.

9. The semiconductor package of claim 1 further comprising through holes for connections for bond pads for a die bound on either the first die attach pad or the second die attach pad.

10. The semiconductor package of claim 1, wherein the semiconductor package is either a quad flat no-leads (QFN) or a dual flat no-leads (DFN).

11. A semiconductor package comprising:
a lead frame including a first die attach pad and a second die attach pad, opposite to the first die attach pad;
a portion of the lead frame between the first die attach pad and the second die attach pad, the portion extending beyond a periphery of the first die attach pad and the second die attach pad;
a die attached to the first die attach pad via a die attach material and electrically connected to a lead; and
a molding that covers portions of the first die attach pad, the die attach material, and the die, wherein a portion of the second die attach pad is exposed from the package, and wherein the lead includes a first surface coplanar with a surface of the first die attach pad, and a the lead includes a second surface coplanar with a surface of the second die attach pad.

12. The semiconductor package of claim 11, wherein the first die attach pad is different in area than the second die attach pad.

13. The semiconductor package of claim 11, wherein the first die attach pad and second die attach pad are about square in area.

14. The semiconductor package of claim 11, wherein the surface of the first die attach pad and the surface of the second die attach pad are on different planes.

15. The semiconductor package of claim 11, wherein the semiconductor package is either a quad flat no-leads (QFN) or a dual flat no-leads (DFN).

16. The semiconductor package of claim 11, wherein the die attach material is made of epoxy, laminate film, or other adhesion material.
